(19) United States
(12) Patent Application Publication
(10) Pub. No.: US 2025/0172623 A1
(43) Pub. Date: May 29, 2025

(54) LITHIUM IRON PHOSPHATE BATTERY CELL END-OF-LINE QUALITY CONTROL PROCESSING

(71) Applicant: FCA US LLC, Auburn Hills, MI (US)

(72) Inventors: Zhongjun Lu, Shanghai (CN); Jingjung Zhao, Shanghai (CN); Wenfeng Yue, Shanghai (CN); Yi Jiang, Shanghai (CN); Lantian Liu, Shanghai (CN)

(21) Appl. No.: 18/522,370

(22) Filed: Nov. 29, 2023

(51) Int. Cl. G01R 31/388; B60L 53/80; G01R 31/378

(52) U.S. Cl. CPC G01R 31/388; B60L 53/80; G01R 31/378

(57) ABSTRACT

Battery cell end-of-line (EOL) quality processing techniques for a lithium iron phosphate (LFP) battery system for an electrified vehicle include determining, for each of a plurality of test LFP battery cells, (i) a minimum state of charge (SOC) threshold and (ii) a self-discharge rate and a self-discharge rate threshold based on the plurality of self-discharge rates, determining whether each LFP battery cell of the LFP battery system passes a cell quality test based on the minimum SOC threshold, the self-discharge rate threshold, and a self-discharge rate of the LFP battery cell, and keeping any of the LFP battery cells of the LFP battery system that pass their respective cell quality tests and replacing any of the LFP battery cells of the LFP battery system that fail their respective cell quality tests to obtain a final EOL LFP battery system.

### FIELD

The present application generally relates to electrified vehicles and, more particularly, to techniques for cell end-of-line (EOL) quality control processing for lithium iron phosphate battery systems for electrified vehicles.

### BACKGROUND

Electrified vehicles include an electric motor powered by a battery system, such as a rechargeable lithium-ion (Li-ion) type battery system. One specific type of Li-ion battery system is lithium iron phosphate (LiFePO4) or “LFP.” LFP battery systems are particularly useful for electrified vehicle applications due to their longer life, higher safety, and lower cost, compared to other Li-ion battery systems (nickel manganese cobalt, or “NMC,” nickel cobalt aluminum, or “NCA,” etc.). One characteristic of LFP battery systems is a voltage “flat zone” where the LFP cells have almost the same voltage across a very wide range of state of charge (SOC), such as between 95% and 15% SOC. In this “flat zone,” however, even significant SOC change due to self-discharge may not be detectable as the target delivery SOC is typically 30% or more (i.e., in the “flat zone”). This could result in poor quality LFP cells not being filtered out, unless caught by a random spot-check, before vehicle delivery. Accordingly, while such conventional LFP battery quality processing systems do work for their intended purpose, there exists an opportunity for improvement in the relevant art.

### SUMMARY

According to one example aspect of the invention, a battery cell end-of-line (EOL) quality processing system for a lithium iron phosphate (LFP) battery system for an electrified vehicle is presented. In one exemplary implementation, the battery cell EOL quality processing system comprises a parameter determination system configured to determine, for each of a plurality of test LFP battery cells, (i) a minimum state of charge (SOC) threshold and (ii) a self-discharge rate and a self-discharge rate threshold based on the plurality of self-discharge rates, a cell quality processing system configured to determine whether each LFP battery cell of the LFP battery system passes a cell quality test based on the minimum SOC threshold, the self-discharge rate threshold, and a self-discharge rate of the LFP battery cell, and an EOL battery arrangement system configured to keep any of the LFP battery cells of the LFP battery system that pass their respective cell quality tests and to replace any of the LFP battery cells of the LFP battery system that fail their respective cell quality tests to obtain a final EOL LFP battery system.

In some implementations, the parameter determination system is configured to select X test LFP battery cells from Y batches of test LFP battery cells, wherein X and Y are each integers greater than one. In some implementations, the parameter determination system is configured to determine values for X and Y based on a representativeness requirement. In some implementations, the self-discharge rate threshold indicates a minimum acceptable drop in open-circuit voltage (OCV) during conditioned storage. In some implementations, the self-discharge rate threshold separates approximately 90% of acceptable quality LFP cells having greater OCV drops from approximately 10% of unacceptable quality LFP cells having lesser OCV drops.

In some implementations, the cell quality processing system is further configured to condition each LFP battery cell of the LFP battery system based on the determined minimum SOC threshold and the self-discharge rate prior to conditioned storage of the LFP battery system. In some implementations, the cell quality processing system is further configured to determine an open-circuit voltage (OCV) of each LFP battery cell of the LFP battery system after the conditioned storage and the quality test determines whether a difference between the expected and actual OCV drop is less than the self-discharge rate threshold. In some implementations, the quality test is a pass when the OCV drop difference is less than the self-discharge rate threshold and is a fail when the OCV drop different is not less than the self-discharge rate threshold. In some implementations, the electrified vehicle is an electrified sport utility vehicle (eSUV).

According to another example aspect of the invention, a battery cell EOL quality processing method for an LFP battery system for an electrified vehicle is presented. In one exemplary implementation, the battery cell EOL quality processing method comprises determining, by a computing system and for each of a plurality of test LFP battery cells, (i) a minimum state of charge (SOC) threshold and (ii) a self-discharge rate and a self-discharge rate threshold based on the plurality of self-discharge rates, determining, by the computing system, whether each LFP battery cell of the LFP battery system passes a cell quality test based on the minimum SOC threshold, the self-discharge rate threshold, and a self-discharge rate of the LFP battery cell, and outputting, by the computing system, instructions to keep any of the LFP battery cells of the LFP battery system that pass their respective cell quality tests and to replace any of the LPF battery cells of the LFP battery system that fail their respective cell quality tests to obtain a final EOL LFP battery system.

In some implementations, the method further comprises selecting, by the computing system, X test LFP battery cells from Y batches of test LFP battery cells, wherein X and Y are each integers greater than one. In some implementations, the method further comprises determining, by the computing system, values for X and Y based on a representativeness requirement. In some implementations, the self-discharge rate threshold indicates a minimum acceptable drop in OCV during conditioned storage. In some implementations, the self-discharge rate threshold separates approximately 90% of acceptable quality LFP cells having greater OCV drops from approximately 10% of unacceptable quality LFP cells having lesser OCV drops.

In some implementations, the method further comprises conditioning, by the computing system, each LFP battery cell of the LFP battery system based on the determined minimum SOC threshold and the self-discharge rate prior to conditioned storage of the LFP battery system. In some implementations, the method further comprises determining, by the computing system, an open-circuit voltage (OCV) of each LFP battery cell of the LFP battery system after the conditioned storage and the quality test determines whether a difference between the expected and actual OCV drop is less than the self-discharge rate threshold. In some implementations, the quality test is a pass when the OCV drop difference is less than the self-discharge rate threshold and is a fail when the OCV drop different is not less than the self-discharge rate threshold. In some implementations, the electrified vehicle is an eSUV.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1A is a plot of open-circuit voltage (OCV) and voltage per state of charge (SOC) change (dV/dSOC) versus SOC for an example lithium iron phosphate (LFP) battery cell according to the principles of the present application;

FIG. 1B is a plot of an example LFP battery cell distribution based on each LFP cell's self-discharge (ΔOCV) during conditioned storage and a filtering threshold (ΔOCV_{TH}) according to the principles of the present application;

FIG. 2A is a flow diagram of an example LFP battery cell testing and quality control parameter determination method according to the principles of the present application;

FIG. 2B is a flow diagram of an example battery cell end-of-line (EOL) quality processing method for an LFP battery system for an electrified vehicle using the quality control parameters determined via the method of FIG. 2A according to the principles of the present application;

FIG. 3A is a functional block diagram of an example LFP battery cell testing and quality control parameter determination system according to the principles of the present application;

FIG. 3B is a functional block diagram of an example battery cell EOL quality processing system configured to obtain a final EOL LFP battery system according to the principles of the present application; and

FIG. 3C is a functional block diagram of an electrified vehicle having the final EOL LFP battery system obtained using the battery cell EOL quality processing system of FIG. 3B according to the principles of the present application.

### DESCRIPTION

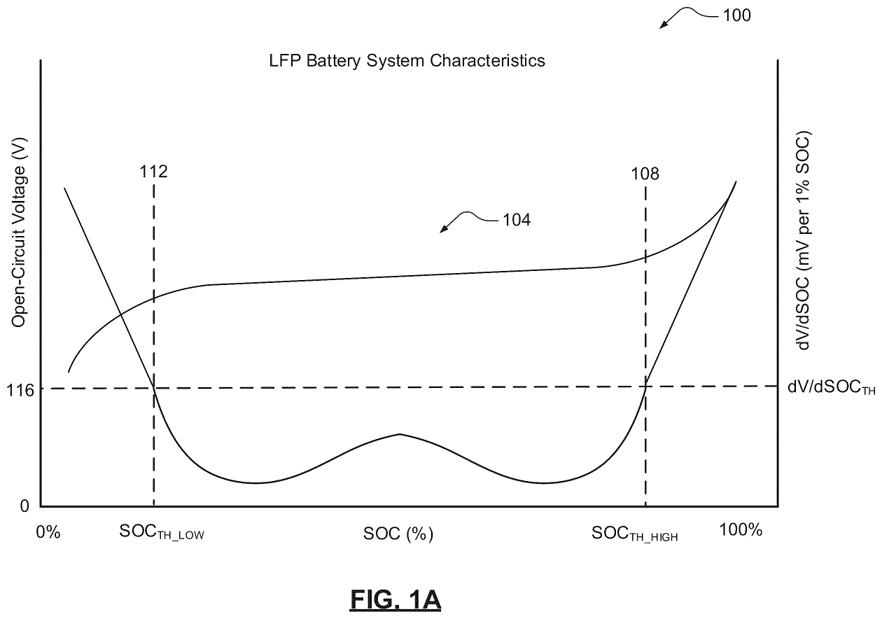

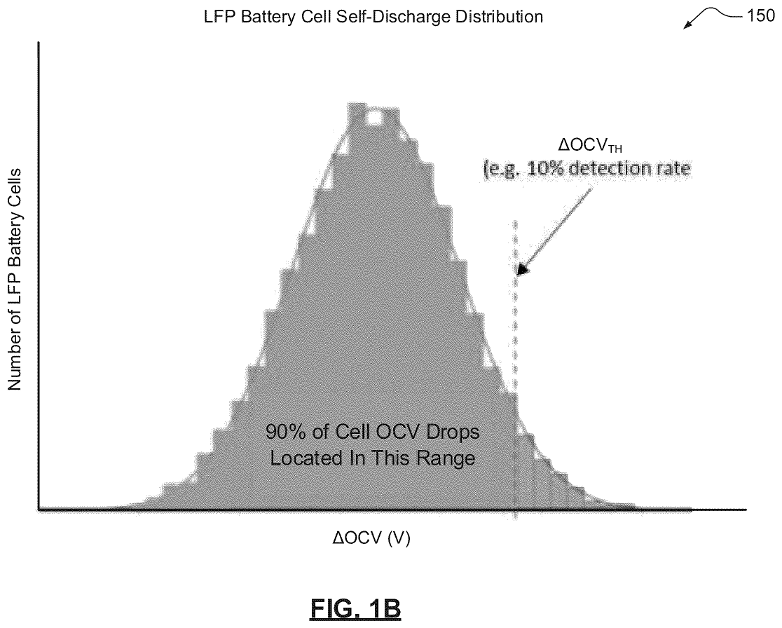

As previously discussed, one specific type of lithium ion (Li-ion) battery system is lithium iron phosphate (LiFePO4) or “LFP.” LFP battery systems are particularly useful for electrified vehicle applications due to their high discharge rates (for vehicle acceleration), lower weight, and longer life, compared to other Li-ion battery systems, such as nickel manganese cobalt (NMC) and nickel cobalt aluminum (NCA). One characteristic of LFP battery systems is a voltage “flat zone,” which refers to LFP cells having almost the same voltage across a very wide range of state of charge (SOC). For example, the LFP cell voltage may be approximately the same between 95% and 15% SOC. FIG. 1A illustrates an example plot 100 of both (i) open-circuit voltage (OCV) versus SOC and (ii) voltage per SOC change (dV/dSOC) versus SOC for an example LFP battery cell according to the principles of the present application. As shown in the plot 100, the voltage flat zone 104 is present between high or maximum and low or minimum SOC thresholds 108 (SOC_{TH_HIGH}) and 112 (SOC_{TH_LOW}), respectively. As previously mentioned, this flat zone 104 creates a problem for conventional LFP battery quality processing techniques, which rely on random spot-checks to identify low/poor quality cells that self-discharge more than desired/acceptable during conditioned storage.

Accordingly, improved techniques for cell end-of-line (EOL) quality processing for LFP battery systems, such as for electrified vehicle applications, are presented herein. These techniques involve initially selecting (e.g., at random) a set of test LFP battery cells and through conditioned storage, measurement, and statistical analysis, determining quality control parameters, such as the minimum SOC voltage threshold SOC_{TH_LOW} that also satisfies a desired dV/dSOC threshold 116 (a target SOC), a conditioned storage duration, and a ΔOCV. For example only, the dV/dSOC threshold dV/dSOC_{TH} could be 2 millivolts (mV) per 1% SOC, but it will be appreciated that other suitable values could be utilized depending on the application. The techniques then condition the LFP battery cells of an LFP battery system intended for a production vehicle using these determined parameters in order to reach a pre-defined quality control target. After the conditioned storage, a quality test is performed on each LFP battery cell to determine whether its OCV voltage drop is acceptable (pass/fail). Failed LFP battery cells are filtered/removed from the LFP battery system and replaced with other (e.g., good/pass quality) LFP battery cells to obtain a final EOL LFP battery system for a production vehicle. As these techniques involve the determination and of cell/battery system parameters or characteristics, this information could also be uploaded and stored in a memory (e.g., non-volatile memory, or NVM) and accessed by a controller of the electrified vehicle during operation, if so desired (e.g., for SOC correction).

Referring now to FIG. 1B and with continued reference to FIG. 1A, a plot or histogram 150 of an example LFP battery cell distribution based on each LFP cell's self-discharge (ΔOCV) during conditioned storage and a filtering threshold (ΔOCV_{TH}) according to the principles of the present application is illustrated. Initially, test LFP battery cells are analyzed to determine parameters or characteristics that are then utilized later by the techniques of the present application to determine pass/fail quality tests for LFP battery cells. This initial selection can include X LFP battery cells from Y LFP battery cell batches, where X and Y are integers greater than one and are determined based on a representativeness requirement or desired representativeness.

As shown in FIG. 1B, this representativeness requirement is such that the self-discharge rate threshold ΔOCV_{TH} separates approximately 90% of acceptable quality LFP cells having greater OCV drops from approximately 10% of unacceptable quality LFP cells having lesser OCV drops. It will be appreciated that this is merely one example distribution and OCV drop threshold ΔOCV_{TH} and that other representativeness criteria and different OCV drop threshold values could be utilized depending on the particular application and/or other factors (e.g., trade-offs between excessive representativeness and minimal quality processing performance improvement). In other words, while maximizing LFP battery system performance and life is very desirable, there is still some finite amount of time during which testing/production must be completed.

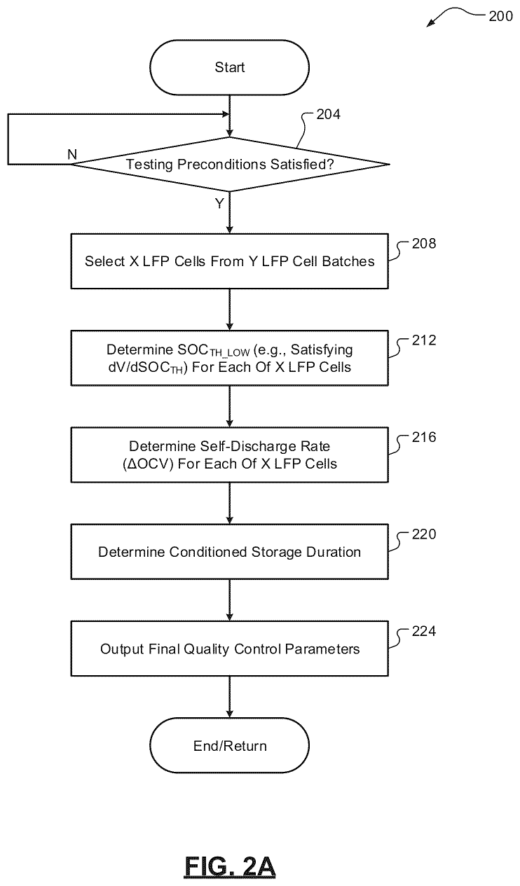

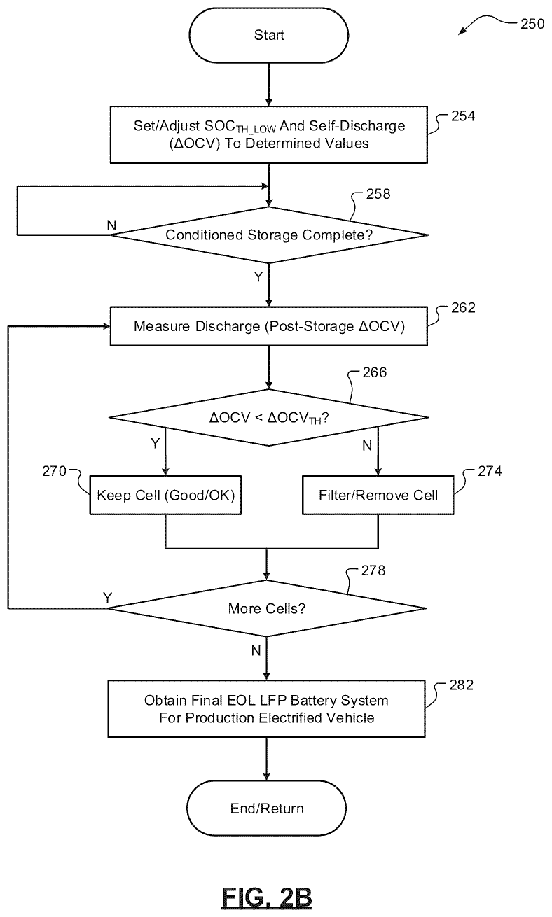

Referring now to FIG. 2A, a flow diagram of an example LFP battery cell testing and quality control parameter determination method 200 according to the principles of the present application is illustrated. At optional 204, one or more testing preconditions could be checked for satisfaction before proceeding with the method 200. This could include, for example only, having a desired or acceptable amount of test LFP battery cells and/or production LFP battery cells. When false, the method 200 ends or returns to 204. Otherwise, the method 200 proceeds to 208. At 208, X test LFP battery cells are selected from Y test LFP battery cell batches as previously discussed herein. At 212 and 216, the minimum SOC threshold SOC_{TH_LOW} (satisfying a corresponding dV/dSOC threshold, dV/dSOC_{TH}) and a self-discharge rate ΔOCV are determined, respectively, for each of the X test LFP battery cells. At 220, a conditioned storage duration is also determined. These three parameters—the conditioned storage duration, the target SOC (minimum SOC threshold SOC_{TH_LOW}), and the ΔOCV—collectively form the final quality control parameters for subsequent usage in a mass production quality control process, which will now be described in greater detail.

Referring now to FIG. 2B, a flow diagram of an example battery cell EOL quality processing method 250 for an LFP battery system for an electrified vehicle (e.g., using the quality control parameters determined via the method of FIG. 2A) according to the principles of the present application is illustrated. The method 250 could be utilized, for example, for the LFP battery system 334 of the electrified vehicle 300, or for any other suitable LFP battery system. At 254, a production LFP battery system having a plurality of LFP battery cells is set/adjusted (i.e., conditioned) based on these previously determined values (from FIG. 2A) SOC_{TH_MIN} and ΔOCV and the LFP battery system is placed in conditioned storage for the conditioned storage period. Once this conditioned storage is complete at 258, the method 250 proceeds to 262 where the self-discharge (ΔOCV) of each LFP battery cell during/after the conditioned storage is measured or determined.

At 266, a quality test is performed for each LFP battery cell to determine whether the OCV drop ΔOCV is less than the self-discharge threshold ΔOCV_{TH}. When true, the LFP battery cell is kept (verified as a good or OK status) at 270 and the method 200 proceeds to 278. When false, the LFP battery cell is filtered or removed (determined as a failed or bad status) at 274 and the method 200 proceeds to 278. At 278, the method 250 determines whether there are any more LFP battery cells to test or to replace in the production LFP battery system. When true, the method 260 returns to 262. Otherwise, the method 200 continues to 282 where the final EOL LFP battery system for a production electrified vehicle is obtained and the method 250 then ends or returns to 254 for another cycle/run.

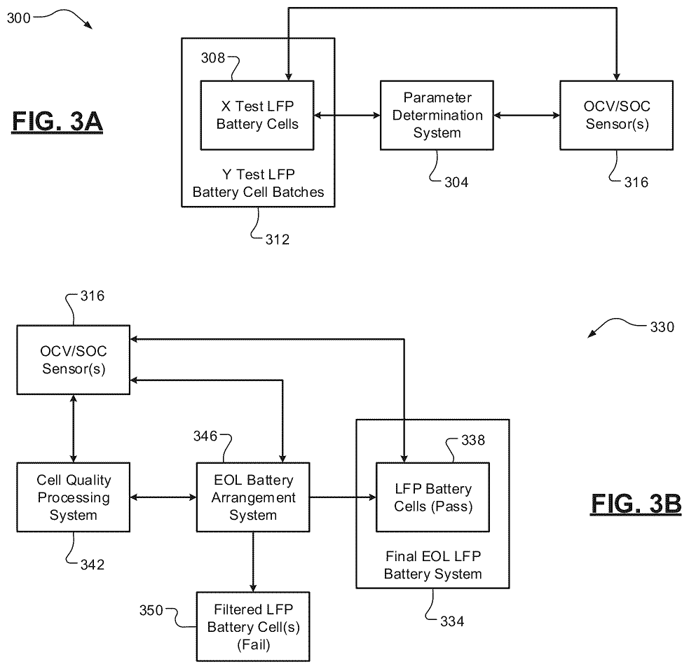

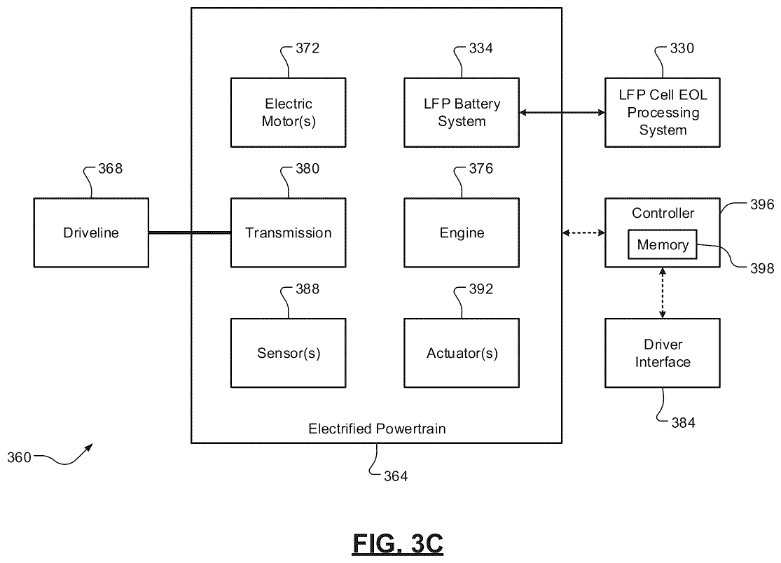

Referring now to FIG. 3A, a functional block diagram of an example LFP battery cell testing and quality control parameter determination system 300 according to the principles of the present application is illustrated. The testing and quality control system 300 could be implemented, for example, as a computer system or a plurality of interconnected computer systems. A parameter determination system 304 determines parameters or characteristics of test LFP battery cells for use in subsequent analysis (i.e., quality test pass/fail). This includes selecting X test LFP battery cells 308 from Y different batches of test LFP battery cells 312, where X and Y are integers greater than one.

The specific values for X and Y can be selected, for example, based on a representativeness requirement or desired representativeness, such as so a self-discharge rate threshold separates approximately 90% of acceptable quality LFP cells having greater OCV drops from approximately 10% of unacceptable quality LFP cells having lesser OCV drops. The parameter determination system 312 is configured to utilize OCV/SOC sensor(s) 316 to monitor/measure various LFP battery system operating parameters. The parameter determination system 312 outputs, to a battery cell EOL quality processing system 330, a set of final quality control parameters: conditioned storage duration, target SOC (the minimum SOC threshold SOC_{TH_MIN}), and ΔOCV.

Referring now to FIG. 3B, a functional block diagram of an example battery cell EOL quality processing system 330 configured to obtain a final EOL LFP battery system 334 according to the principles of the present application is illustrated The final EOL LFP battery system 334 includes a plurality of LFP battery cells 338 that are determined to have passed respective quality tests as discussed herein. A cell quality processing system 342 is configured to perform a quality test on each LFP battery cell of an LFP battery system being considered for a production vehicle. Each cell quality test can be based on the minimum SOC threshold (SOC_{TH_MIN}), the self-discharge rate threshold (ΔOCV_{TH}), and a self-discharge rate of the respective/tested LFP battery cell. This could include, for example, determining an OCV of each LFP battery cell of the LFP battery system after the conditioned storage and the quality test determines whether a difference between the expected and actual OCV drop is less than the self-discharge rate threshold ΔOCV_{TH}. More specifically, the quality test is a pass when the OCV drop difference is less than the self-discharge rate threshold and is a fail when the OCV drop different is not less than (greater than) the self-discharge rate threshold.

Finally, the EOL battery arrangement system 346 keeps any of the LFP battery cells 338 that pass their respective cell quality tests and filters or removes LFP battery cells 350 that fail their respective cell quality tests. Any empty slots corresponding to filtered/removed LFP battery cells 350 are then replaced with other LFP battery cells, such as LFP battery cells from another group/batch that have passed their respective cell quality tests. The final EOL LFP battery system 334 is then obtained for a production vehicle.

Referring now to FIG. 3C, a functional block diagram of an electrified vehicle 360 having an example LFP battery system 334 resulting from the cell quality processing techniques (performed by the external LFP cell EOL processing system 330 shown in detail in FIG. 3B and described above) according to the principles of the present application is illustrated. The electrified vehicle 360 could have any suitable configuration, including, but not limited to, a battery electric vehicle (BEV), a plug-in hybrid electric vehicle (PHEV), and a range-extended electric vehicle (REEV). In one exemplary implementation, the electrified vehicle 360 is an electrified sport utility vehicle (eSUV). The electrified vehicle 360 comprises an electrified powertrain 364 including the LFP battery system 334 and configured to generate and transfer drive torque to a driveline 368 for vehicle propulsion.

The electrified powertrain 364 comprises one or more electric motors 372 powered by the LFP battery system 334 and an optional internal combustion engine 376 configured to combust a mixture of air and fuel (gasoline, diesel, etc.) to generate torque. The torque generating devices 372, 376 are configured to collectively generate an amount of drive torque to satisfy a driver torque request, which is then transferred to the driveline 368 via a transmission 380 (e.g., a multi-speed, torque converted automatic transmission). The driver torque request could be provided by a driver via a driver interface 384, which could include various input/output devices including, but not limited to, accelerator/brake pedals, a display device, and a power on/off switch for the electrified vehicle 360.

The electrified powertrain 364 also has one or more sensors 388 and one or more actuators 392 associated therewith. These sensor(s) 388 measure various operating parameters of the electrified vehicle 360, including, but not limited to, current/voltage/temperature of the LFP battery system 334 and ambient temperature. The actuator(s) 392 control various components of the electrified powertrain 364, such as, but not limited to, power (e.g., current) provided to the electric motor(s) 372 and torque control devices (throttle valve, fuel injectors, a spark/ignition system, not shown) of the engine 376 such that the driver torque request is satisfied.

A controller 396 having a memory 398 (e.g., NVM) controls operation of the electrified vehicle 360 and, more particularly, the electrified powertrain 364. In some implementations, the controller 396 is also configured to perform control techniques based on the uploaded/stored parameters obtained during the LFP cell EOL processing techniques, such as static SOC correction for the LFP battery system 334 or the like. In other words, the previous pre-delivery testing of the LFP battery system 334 and, more particularly, its LFP battery cells and their characteristics, could be leveraged to have access to this information for other purposes/benefits by the electrified vehicle 360.

It will be appreciated that the term “controller” as used herein refers to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A battery cell end-of-line (EOL) quality processing system for a lithium iron phosphate (LFP) battery system for an electrified vehicle, the battery cell EOL quality processing system comprising:
a parameter determination system configured to determine, for each of a plurality of test LFP battery cells, (i) a minimum state of charge (SOC) threshold and (ii) a self-discharge rate and a self-discharge rate threshold based on the plurality of self-discharge rates;
a cell quality processing system configured to determine whether each LFP battery cell of the LFP battery system passes a cell quality test based on the minimum SOC threshold, the self-discharge rate threshold, and a self-discharge rate of the LFP battery cell; and
an EOL battery arrangement system configured to keep any of the LFP battery cells of the LFP battery system that pass their respective cell quality tests and to replace any of the LFP battery cells of the LFP battery system that fail their respective cell quality tests to obtain a final EOL LFP battery system.

2. The battery cell EOL quality processing system of claim 1, wherein the parameter determination system is configured to select X test LFP battery cells from Y batches of test LFP battery cells, wherein X and Y are each integers greater than one.

3. The battery cell EOL quality processing system of claim 2, wherein the parameter determination system is configured to determine values for X and Y based on a representativeness requirement.

4. The battery cell EOL quality processing system of claim 1, wherein the self-discharge rate threshold indicates a minimum acceptable drop in open-circuit voltage (OCV) during conditioned storage.

5. The battery cell EOL quality processing system of claim 4, wherein the self-discharge rate threshold separates approximately 90% of acceptable quality LFP cells having greater OCV drops from approximately 10% of unacceptable quality LFP cells having lesser OCV drops.

6. The battery cell EOL quality processing system of claim 1, wherein the cell quality processing system is further configured to condition each LFP battery cell of the LFP battery system based on the determined minimum SOC threshold and the self-discharge rate prior to conditioned storage of the LFP battery system.

7. The battery cell EOL quality processing system of claim 6, wherein the cell quality processing system is further configured to determine an open-circuit voltage (OCV) of each LFP battery cell of the LFP battery system after the conditioned storage and the quality test determines whether a difference between the expected and actual OCV drop is less than the self-discharge rate threshold.

8. The battery cell EOL quality processing system of claim 7, wherein the quality test is a pass when the OCV drop difference is less than the self-discharge rate threshold and is a fail when the OCV drop different is not less than the self-discharge rate threshold.

9. The battery cell EOL quality processing system of claim 1, wherein the electrified vehicle is an electrified sport utility vehicle (eSUV).

10. A battery cell end-of-line (EOL) quality processing method for a lithium iron phosphate (LFP) battery system for an electrified vehicle, the battery cell EOL quality processing method comprising:
determining, by a computing system and for each of a plurality of test LFP battery cells, (i) a minimum state of charge (SOC) threshold and (ii) a self-discharge rate and a self-discharge rate threshold based on the plurality of self-discharge rates;
determining, by the computing system, whether each LFP battery cell of the LFP battery system passes a cell quality test based on the minimum SOC threshold, the self-discharge rate threshold, and a self-discharge rate of the LFP battery cell; and
outputting, by the computing system, instructions to keep any of the LFP battery cells of the LFP battery system that pass their respective cell quality tests and to replace any of the LFP battery cells of the LFP battery system that fail their respective cell quality tests to obtain a final EOL LFP battery system.

11. The battery cell EOL quality processing method of claim 10, further comprising selecting, by the computing system, X test LFP battery cells from Y batches of test LFP battery cells, wherein X and Y are each integers greater than one.

12. The battery cell EOL quality processing method of claim 11, further comprising determining, by the computing system, values for X and Y based on a representativeness requirement.

13. The battery cell EOL quality processing method of claim 10, wherein the self-discharge rate threshold indicates a minimum acceptable drop in open-circuit voltage (OCV) during conditioned storage.

14. The battery cell EOL quality processing method of claim 13, wherein the self-discharge rate threshold separates approximately 90% of acceptable quality LFP cells having greater OCV drops from approximately 10% of unacceptable quality LFP cells having lesser OCV drops.

15. The battery cell EOL quality processing method of claim 10, further comprising conditioning, by the computing system, each LFP battery cell of the LFP battery system based on the determined minimum SOC threshold and the self-discharge rate prior to conditioned storage of the LFP battery system.

16. The battery cell EOL quality processing method of claim 15, further comprising determining, by the computing system, an open-circuit voltage (OCV) of each LFP battery cell of the LFP battery system after the conditioned storage and the quality test determines whether a difference between the expected and actual OCV drop is less than the self-discharge rate threshold.

17. The battery cell EOL quality processing method of claim 16, wherein the quality test is a pass when the OCV drop difference is less than the self-discharge rate threshold and is a fail when the OCV drop different is not less than the self-discharge rate threshold.

18. The battery cell EOL quality processing method of claim 10, wherein the electrified vehicle is an electrified sport utility vehicle (eSUV).
